(19) United States
(12) Patent Application Publication
(10) Pub. No.: US 2009/0022572 A1
(43) Pub. Date: Jan. 22, 2009

(54) Cluster tool with a linear source

(76) Inventors: Thomas Pass, San Jose, CA (US); Hsin-Chiao Luan, Palo Alto, CA (US)

Correspondence Address: Jennifer Hayes;BLAKELY, SOKOLOFF, TAYLOR & ZAFMAN LLP, 1279 Oakmead Parkway, Sunnyvale, CA, 94085-4040, US

(21) Appl. No.: 11/880,280

(22) Filed: Jul. 19, 2007

(51) Int. Cl. H01L 21/677

(52) U.S. Cl. 414/222.13; 414/806; 901/1

(57) ABSTRACT

Systems and methods combining a cluster chamber with linear sources are described. A plurality of wafers is mounted on a pallet. A central robot in a cluster chamber moves the pallet among chambers connected to the cluster chamber chamber. At least one of the chambers connected to the cluster chamber includes a linear deposition source, the pallet moveable relative to the linear deposition source.

### TECHNICAL FIELD

This invention relates to the field of wafer deposition and, in particular, to a sputtering system combining a cluster tool with linear sources.

### BACKGROUND

Deposition systems are used to deposit a substance on a substrate. Several types of conventional deposition systems are currently implemented. One type of conventional deposition system implements magnetron sputtering. Sputtering, in general, is the process of ejecting atoms from a solid target material, the target or cathode, to deposit a thin film on a substrate. A magnetron enhances this operation by generating strong electric and magnetic fields to trap electrons and improve the formation of ions from gaseous neutrals such as argon. The ions impact the target and cause target material to eject and deposit on the substrate.

One exemplary deposition system is a cluster tool. Cluster tools include a central robot having several chambers radially extending from the centrally located robot. The deposition chambers include a stationary deposition source. In these cluster tools, a single wafer or, at most, two wafers, are moved among the chambers by the central robot, the wafer positioned under a stationary cathode.

Another exemplary deposition system is an in-line deposition system. In in-line deposition systems, several sources are arranged linearly. A pallet of wafers are passed under each of the sources in-line. The length of these in-line deposition systems is typically very large (on the order of 150 feet long).

The Kurt J. Lesker Company makes a combined multi-chamber cluster tool system (OCTOS® Cluster Tool Deposition System), which processes single substrates having a size of 6″×6″ or smaller.

### BRIEF DESCRIPTION OF THE DRAWINGS

Embodiments of the invention are described by way of example with reference to the accompanying drawings, wherein:

FIG. 1 is a schematic view of a cluster tool with linear sources in accordance with one embodiment of the invention;

FIG. 2 is a detailed schematic view of a deposition chamber in accordance with one embodiment of the invention; and

FIG. 3 is a process flow diagram of a deposition process in accordance with one embodiment of the invention.

### DETAILED DESCRIPTION

The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

Embodiments of the invention relate to a combined cluster tool and in-line deposition chamber. Embodiments of the invention also relate to a combined cluster tool and in-line deposition chamber having a redundant in-line deposition chamber. Embodiments of the invention also relate to a combined cluster tool and in-line deposition chamber configured to handle a pallet having wafers mounted thereon.

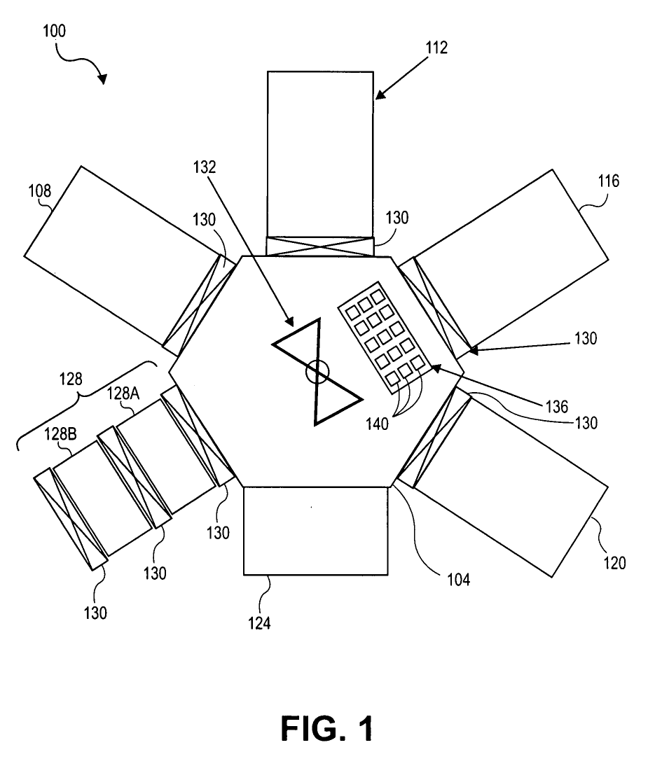

FIG. 1 illustrates a deposition system 100 in accordance with one embodiment of the invention. The deposition system includes a cluster chamber 104 and a plurality of chambers 108-128. The plurality of chambers 108-128 extend radially from the cluster chamber. In general, a vacuum is maintained among the cluster chamber 104 and chambers 108-128. Valves 130 may be provided between the cluster chamber 104 and each of the chambers 108-128 to maintain the vacuum or isolate the vacuum. In one embodiment, the cluster chamber 104 is in high vacuum.

In one embodiment, the plurality of chambers 108-124 include a first deposition chamber 108, a second deposition chamber 112, a third deposition chamber 116, a fourth deposition chamber 120, a buffer chamber 124 and a combined rough and isolation chamber 128. In one embodiment, the buffer chamber 124 is configured to store a plurality of pallets. In one embodiment, one of the deposition chambers is a redundant chamber. Thus, a deposition process need not be shut down when one of the deposition chambers is cleaned. In one embodiment, the buffer chamber 124 includes elevators for storing the plurality of pallets. In one embodiment, the combined rough and isolation chamber 128 includes a rough chamber 128a and an isolation chamber 128b separated from one another with a valve 130 to maintain a vacuum. It will be appreciated that the actual number and type of chambers may vary from that illustrated and described. For example, fewer or greater than four deposition chambers may be provided. In another example, a buffer chamber need not be provided. In a further example, a heating chamber may be provided in addition to or in the alternative of the illustrated chambers.

In one particular embodiment, the first deposition chamber 108 is configured to deposit Al—Si, the second deposition chamber 112 is configured to deposit Ti—W, the third deposition chamber 116 is configured to deposit Cu, and the fourth deposition chamber 120 is a redundant chamber.

As will be described in further detail hereinafter, one or more of the deposition chambers 108-120 is an in-line deposition chamber.

The cluster chamber 104 includes a central robot 132. The central robot 132 is configured to move a pallet 136 among the chambers 108-128 through the cluster chamber 104. The central robot 132 is also configured to position the pallet 136 on a transport mechanism in one or more of the chambers 108-128 as described in further detail hereinafter. It will be appreciated that more than one robot may be provided in the cluster chamber and/or that the robot(s) may be configured to carry one or more pallets.

The pallet 136 is illustrated in the cluster chamber 104 in FIG. 1. The pallet 136 is configured to carry a plurality of wafers 140. In one embodiment, the wafers are mounted on the pallet 136 in the cluster chamber. In another embodiment, the wafers are mounted on the pallet 136 in one of the plurality of chambers. In another embodiment, the wafers are mounted on the pallet 136 external the deposition system 100.

In one embodiment, the pallet includes wafer pockets to receive wafers therein. In another embodiment, the wafers are positioned on a substantially flat pallet (e.g., without wafer pockets). In embodiments with a substantially flat pallet, the pallet may include pins or clips to hold the wafers in a predefined arrangement. In one embodiment, the pallet and wafers are electrically isolated. In one embodiment, the pallet and transport mechanism include an isolated anode. The anode serves as an anode to a deposition source in one or more of the chambers.

In one embodiment, the wafers are solar cell wafers or photovoltaic cell wafers. In one embodiment, the wafers are silicon. In one embodiment, the wafer has a substantially rectangular shape.

In one embodiment, the deposition system 100 is configured to make thin film solar cells. For example, the central robot 132 may be configured to transfer a glass sheet among the chambers 108-128 through the cluster chamber 104.

In use, wafers 140 are mounted on the pallet 136. In one embodiment, the wafers 140 are mounted on the pallet 136 in the cluster chamber 104. In another embodiment, the wafers 140 are mounted on the pallet 136 external the deposition system 100, and the pallet 136 enters the deposition system 136 through, for example, the isolation chamber 128b. The central robot 132 moves the pallet 136 from the cluster chamber 104 to the first deposition chamber 108. After processing is complete in the first deposition chamber 108, the central robot 132 retrieves the pallet 136 and moves the pallet 136 to the second deposition chamber 112 through the cluster chamber 104. Similarly, after processing is complete in the second deposition chamber 112, the central robot 132 retrieves the pallet 136 from the second deposition chamber 112 and moves the pallet 136 to the third deposition chamber 116 through the cluster chamber. The central robot 132 similarly transfers the pallet from the third deposition chamber 116 to the fourth deposition chamber 120, buffer chamber 124 and rough and isolation chamber 128. It will be appreciated that the process may vary from the process described above. It will also be appreciated that more than one pallet may be processed in the deposition system 100 simultaneously.

In general, one of the deposition chambers is redundant such that the system is not entirely shut down during servicing. In the above example, the fourth deposition is the redundant chamber. However, it will be appreciated that the fourth chamber may also be used as a deposition chamber (i.e., to deposit four layers on the substrate). It will also be appreciated that the first, second or third deposition chambers may instead be the redundant chamber and that the material deposited in each deposition chamber may vary depending on the servicing schedule.

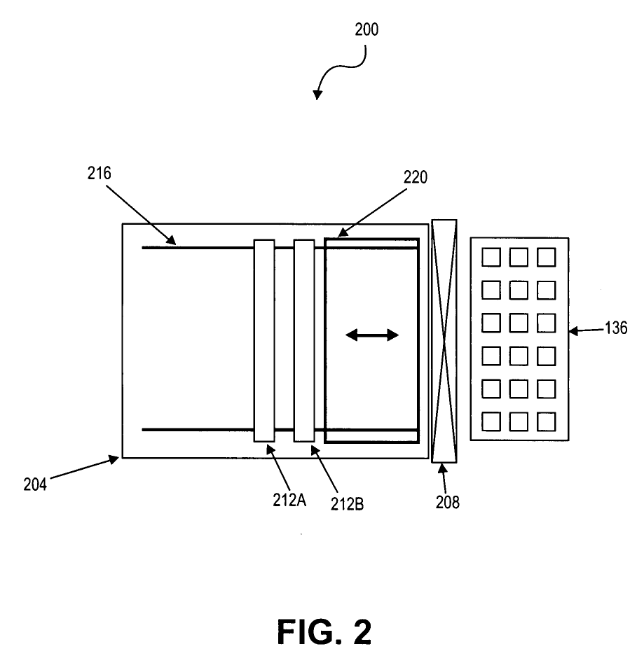

FIG. 2 illustrates a deposition chamber 200 in accordance with one embodiment of the invention. In one embodiment, one or more of the deposition chambers 108-120 have a configuration as shown in FIG. 2.

The deposition chamber 200 includes a housing 204, a gate valve 208, a linear deposition source 212, transport rails 216 and a carrier 220. The housing 204 of the deposition chamber 200 is connected to the cluster chamber 104 of FIG. 1 via the gate valve 208. The gate valve 208 is used to isolate the vacuum for servicing and for changing the operating pressure of the deposition chambers separate from the cluster chamber pressure. It will also be appreciated that the valve is open during transfer of the pallet.

In FIG. 2, two linear deposition sources 212a, 212b are illustrated. It will be appreciated, however, that fewer than two or greater than two linear deposition sources may be provided in the chamber 200. In one embodiment, one or more linear deposition sources are provided in combination with one or more stationary sources in the chamber 200. In one embodiment, one or more linear sources are position on a top interior surface and a bottom interior surface of the housing 204. In another embodiment, linear sources are placed on opposing sides of the housing 204. In one embodiment, the linear source is a plurality of point sources arranged linearly. The linear source may include a planar magnetron, a cylindrical magnetron, or the like.

The carrier 220 is movably mounted on the transport rails 216. The carrier 220 is configured to receive the pallet 136 and move the pallet under the linear source 212 via the transport rails 216. It will be appreciated that methods other than illustrated in FIG. 2 can be used to move the pallet relative to the linear source. For example, the pallet 136 can be placed on fixed transport rails and the pallet is moved directly. In another example, the pallet 136 is placed on moveable transport rails (i.e., without a carrier). In yet another example, a moving belt and rollers may be provided to move the pallet relative to the linear source. In another embodiment, the pallet remains stationary while the linear source is moveable relative to the pallet. Similarly, in another embodiment, both the pallet and the linear source are moveable.

In one embodiment, a plurality of carriers may be provided to move one or more pallets. Similarly, the carrier 220 may be configured to move a plurality of pallets relative to the linear source. In one embodiment, the pallets pass over or under each other in the deposition chamber. For example, one pallet may pass over the transport rails and under the linear source at one level, while another pallet passes under the transport rails at another level. Similarly, the deposition chamber may include multiple deposition levels.

In use, the pallet 136 is positioned on the carrier 220 by the central robot 132 of FIG. 1. The carrier 220 is moved on the transport rails 216 relative to the linear deposition source 212 to move the pallet relative to the source. The source deposits material(s) on the wafers when the pallet passes under the source(s). As discussed above, exemplary deposition materials include Al—Si, Ti—W, Cu and the like. After deposition, the carrier 220 returns the pallet 136 to the entrance of the chamber 200 such that the robot 132 can remove the pallet from the deposition chamber 200 for additional processing.

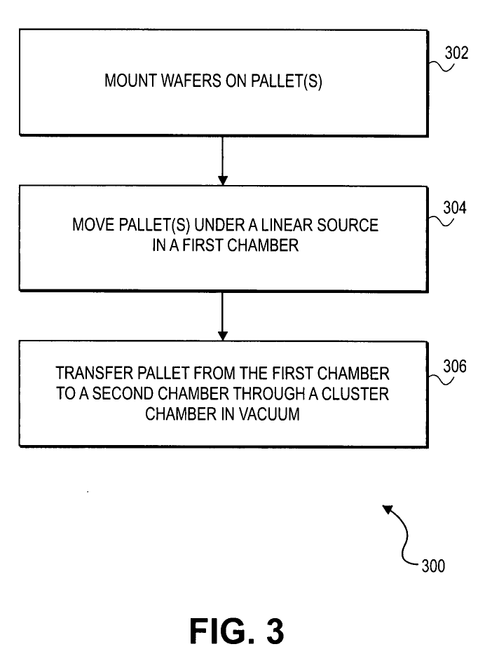

FIG. 3 illustrates a process 300 of processing a substrate using the deposition system 100. The process 300 begins by mounting wafers on a pallet (block 302). The process 300 continues by moving the pallet under a linear source in a first chamber (block 304). The process 300 continues by transferring the pallet from the first chamber to a second chamber through a cluster chamber in vacuum (block 306). It will be appreciated that the process 300 may vary from that illustrated and described as discussed hereinabove.

In one embodiment, the first deposition chamber 108 includes a linear source to deposit Al and Si; the second deposition chamber 112 includes a linear source to deposit Ti and W; the third deposition chamber 116 includes a linear source to deposit Cu; and the fourth deposition chamber 120 is a redundant chamber. The fourth deposition chamber 120 allows for continuous operation of the deposition system 100. In one embodiment, multiple sources may be provided in each chamber to allow for matching of deposition rates or PM cycles to compensate for different layer thicknesses, consumption rates and/or target thicknesses. It will be appreciated that the actual number of chambers, deposition materials, and number and type of sources, etc., may vary from that described above.

A typical cluster tool is a precision deposition tool designed for improved uniformity and process control by using a stationary source and isolated chambers, high overall equipment efficiency (OEE) by using redundant chambers, small footprint and low particle generation. A typical in-line tool is a mass deposition tool designed for high throughput (by multiple orders compared with cluster tools) operation with significantly higher downtime interval lengths, a large footprint, and moderately high particle generation. Combining advantages of the two systems provides, for example, high throughput, moderate uniformity precision, process isolation and high OEE with limited downtime interval lengths.

Advantages of the embodiments described above also include, for example, multiple wafers can be mounted on a pallet and processed under an in-line source without using a conventional in-line tool. When using pallets, the combined deposition system allows a higher OEE than a conventional in-line tool because the individual deposition chambers can be vented without stopping the process or venting the other chambers. The moving pallet allows use of a linear deposition source that is smaller in area than the pallet as opposed to a stationary source which must be the same size as the pallet. In addition, the coating uniformity on the pallet from the linear source is easier to control than a stationary deposition source covering the same pallet area. The functioning of the pallet to carry wafers can be separated from the functions of the pallet as a transport mechanism by itself or in combination with the carrier or transport mechanism. The deposition conditions within each deposition chamber can be easily varied compared to a conventional in-line tool. With open carriers and pallet trays, deposition can occur on both sides of the substrate. The combined system reduces facilities servicing compared to a conventional in-line tool because the overall footprint of the deposition system is reduced.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A method comprising:
receiving a plurality of wafers in a first chamber of a cluster tool; and
moving the plurality of wafers under a linear source in the first chamber of the cluster tool.

2. The method of claim 1, further comprising moving a pallet under the linear source, the plurality of wafers on the pallet.

3. The method of claim 1, further comprising transferring the plurality of wafers from the first chamber to a second chamber through a cluster chamber in the cluster tool.

4. The method of claim 3, further comprising moving the plurality of wafers under a linear source in the second chamber.

5. The method of claim 3, further comprising transferring the plurality of wafers from the second chamber to a third chamber through the cluster chamber in vacuum.

6. The method of claim 5, further comprising moving the plurality of wafers under a linear source in the third chamber.

7. The method of claim 1, further comprising moving a plurality of pallets under the linear source in the first chamber.

8. The method of claim 1, wherein moving the plurality of wafers under a linear source comprises moving the plurality of wafers under a first linear source and a second linear source.

9. The method of claim 1, wherein moving the plurality of wafers under a linear source comprises moving the plurality of wafers under a plurality of linear sources.

10. The method of claim 1, wherein moving the plurality of wafers under a linear source comprises moving the pallet between a first linear source and a second linear source.

11. The method of claim 1, further comprising mounting the plurality of wafers on a pallet.

12. The method of claim 1, wherein the wafers are solar cell wafers.

13. The method of claim 2, further comprising mounting the pallet on a carrier in the first chamber of the cluster tool and wherein moving the pallet under the linear source comprises moving the carrier under the linear source.

14. The method of claim 1, further comprising mounting the plurality of wafers on a pallet fixed in the first chamber.

15. A system comprising:
a first chamber having a linear source and a carrier to move a plurality of wafers under the linear source;
a second chamber; and
a cluster chamber connecting the first chamber with the second chamber, the cluster chamber having a robot to transfer the plurality of wafers between the first chamber and the second chamber.

16. The system of claim 15, wherein the second chamber comprises a second linear source and a second carrier to move a plurality of wafers under the second linear source.

17. The system of claim 15, further comprising a third chamber, the cluster chamber connecting the first chamber, second chamber and third chamber, and wherein the robot transfers the plurality of wafers among the first chamber, second chamber and third chamber.

18. The system of claim 15, wherein the first chamber comprises a plurality of linear sources.

19. The system of claim 15, wherein the first chamber comprises a plurality of carriers.

20. The system of claim 15, wherein the first chamber further comprises a stationary source.

21. The system of claim 15, wherein the carrier is open.

22. The system of claim 15, further comprising a pallet, the plurality of wafers positioned on the pallet, the pallet moveable by the carrier.

23. A system comprising:
a first chamber having a linear source and transport rails to move a pallet having a plurality of wafers under the linear source;
a second chamber; and
a cluster chamber connecting the first chamber with the second chamber, the cluster chamber having a robot to transfer the pallet between the first chamber and the second chamber.

24. The system of claim 23, wherein the second chamber comprises a second linear source and a second carrier to move a pallet having a plurality of wafers under the second linear source.

25. The system of claim 23, further comprising a third chamber, the cluster chamber connecting the first chamber, second chamber and third chamber, and wherein the robot transfers the pallet among the first chamber, second chamber and third chamber.

26. The system of claim 23, wherein the first chamber comprises a plurality of linear sources.

27. The system of claim 23, wherein the first chamber further comprises a stationary source.

28. The system of claim 23, wherein the pallet is open.

29. A cluster tool comprising:
a plurality of chambers, at least one of the plurality of chambers having a linear source and being configured to receive a pallet of wafers, the pallet of wafers moveable relative to the linear source.

30. The cluster tool of claim 29, further comprising a robot to transfer the pallet of wafers among the plurality of chambers.
